(19) United States
(12) Patent Application Publication
(10) Pub. No.: US 2008/0238514 A1
(43) Pub. Date: Oct. 2, 2008

(54) LEVEL-CONVERTED AND CLOCK-GATED LATCH AND SEQUENTIAL LOGIC CIRCUIT HAVING THE SAME

(76) Inventor: MIN-SU KIM, Hwaseong-si (KR)

Correspondence Address: F. CHAU & ASSOCIATES, LLC, 130 WOODBURY ROAD, WOODBURY, NY, 11797, US

(21) Appl. No.: 12/060,475

(22) Filed: Apr. 1, 2008

(30) Foreign Application Priority Data
Apr. 2, 2007 (KR) 10-2007-0032264

(51) Int. Cl. H03K 3/356

(52) U.S. Cl. 327/212

(57) ABSTRACT

A level-converted and clock-gated latch includes a pulse generator, a level converting unit, and a latch circuit. The pulse generator is provided with a first power-supply voltage and generates a pulse signal having a first voltage level, in response to a clock signal. The level converting unit is provided with a second power-supply voltage and generates an intermediate clock signal having a second voltage level, in response to an inverted clock signal, the clock signal and an enable signal. The latch circuit is provided with the second power-supply voltage, latches the intermediate clock signal, and provides a gated clock signal having the second voltage level. An activation interval of the gated clock signal is controlled based on the enable signal.

### CROSS-REFERENCE TO RELATED APPLICATION

This application claims priority under 35 USC §119 to Korean Patent Application No. 2007-0032264, filed on Apr. 2, 2007 in the Korean Intellectual Property Office (KIPO), the disclosure of which is incorporated herein in its entirety by reference.

### BACKGROUND OF THE INVENTION

1. Technical Field

The present disclosure relates to a semiconductor integrated circuit and, more particularly, to a gated latch.

2. Discussion of Related Art

Digital logic circuits can generally be characterized as either combinational circuits or sequential circuits. Combinational circuits are based on logic gates, and outputs of the logic gates are directly determined by the present input values applied to the circuit. Combinational circuits perform operations that are logically specified by a series of Boolean expressions. Sequential circuits may also include logic gates, but additionally employ storage devices such as flip-flops. The outputs of the storage devices depend not only on the values of some present inputs, but also on the values of some previous inputs. Thus, the operation of sequential logic circuits is characterized by internal states, as well as a time sequence of the inputs thereof.

All digital systems include combinational circuits, and most digital systems also include storage devices such as latches. Examples of the storage devices employing flip-flops include latches, registers, counters, static memory arrays, and so forth. Because the operation of flip-flops affects speed and power of the digital systems, it is very important to effectively design sequential logic circuits in order to achieve high-speed and low-power operation.

Particularly, clock-gated logic circuits have been introduced to reduce power consumed by flip-flops.

FIG. 1 is circuit diagram illustrating a conventional clock-gated logic circuit.

Referring to FIG. 1, the clock-gated logic circuit generates a gated clock signal GCK that is synchronized with a clock signal CK while a control signal EN or TE is active. The amplitude of the gated clock signal GCK is substantially the same as the amplitude of the clock signal CK. In recently proposed high-speed and low-power systems, the clock signal generator is provided with a low power-supply voltage, and the flip-flops are provided with a high power-supply voltage. In the circuit illustrated in FIG. 1, however, when the amplitude of the gated clock signal GCK is substantially the same as the amplitude of the clock signal CK, a delay increases in the critical path of the flip-flop. Thus, performance of the flip-flop is degraded. In addition, a large amount of short-circuited current may occur in parts where the high power-supply voltage is applied.

FIG. 2 is a circuit diagram illustrating that a gated clock signal GCK having a low swing level is applied to an inverter that is provided with a high voltage.

Assuming that the gated clock signal GCK swings between 0[V] and 1[V], and voltage level of the power-supply voltage VDDH is 2[V]. The power-supply voltage VDDH is connected to a p-type metal oxide semiconductor (PMOS) transistor MP included in an inverter 10. Assuming that each threshold voltage of the PMOS transistor MP and an n-type metal oxide semiconductor (NMOS) transistor MN is 0.5[V]. When the gated clock signal GCK is a low level, that is, 0[V], the inverter 10 operates normally. When the gated clock signal GCK is a high level, that is, 1[V], gate-source voltage of the NMOS transistor MN corresponds to 1[V] and, thus, the NMOS transistor MN is turned on. When the gate-source voltage of the NMOS transistor MN corresponds to 1[V], gate-source voltage of the PMOS transistor MP also corresponds to 1[V] and, thus, the PMOS transistor MP is also turned on. Accordingly, a large amount of short-circuited current flows through a current path from the power-supply voltage VDDH to the ground voltage via the PMOS transistor MP and the NMOS transistor MN. The short-circuited current increases power consumption. For preventing such a short-circuited current, a scheme is introduced in which a gated clock signal GCK via a level converter is applied to the flip-flop.

FIG. 3 illustrates that a gated clock signal via a level converter is applied to the flip-flop.

Is Referring to FIG. 3, a voltage level of the gated clock signal GCK is increased by a level converter 20, and a level converted gated clock signal is applied to the flip-flop 30. The short-circuited current may be prevented, however, overall circuit size increases because of the level converter 20.

### SUMMARY OF THE INVENTION

Accordingly, exemplary embodiments of the present invention are provided to substantially obviate one or more problems due to limitations and disadvantages of the conventional art.

Exemplary embodiments of the present invention provide a level-converted and clock-gated latch, without requiring an extra level converter.

Exemplary embodiments of the present invention provide a sequential logic circuit including a level-converted and clock-gated latch.

In exemplary embodiments of the present invention, a level-converted and clock-gated latch includes a pulse generator, a level converting unit, and a latch circuit. The pulse generator is provided with a first power-supply voltage and generates a pulse signal having a first voltage level, in response to a clock signal. The level converting unit is provided with a second power-supply voltage and generates an intermediate clock signal having a second voltage level, in response to an inverted clock signal, the clock signal, and an enable signal. The latch circuit is provided with the second power-supply voltage, latches the intermediate clock signal, and provides a gated clock signal having the second voltage level. An activation interval of the gated clock signal is controlled based on the enable signal.

In exemplary embodiments, the level of the first power-supply voltage may be lower than the level of the second power-supply voltage.

In exemplary embodiments, the pulse generator may include a first inverter, a delay unit, and a pulse signal providing unit. The first inverter inverts the clock signal to provide the inverted clock signal. The delay unit delays the inverted clock signal to provide an inverted and delayed clock signal. The pulse signal providing unit provides the pulse signal, based on the clock signal and the inverted and delayed clock signal. In this exemplary embodiment, the pulse signal may be activated while the clock signal and the inverted and delayed clock signal are simultaneously activated. The delay unit may include an even number of inverters that are coupled in cascade. The activation interval of the pulse signal may be controlled based on the number of inverters included in the delay unit.

In exemplary embodiments, the pulse signal providing unit may include a NAND gate that receives the inverted and delayed clock signal and the clock signal and a second inverter that inverts an output of the NAND gate to provide the pulse signal.

In exemplary embodiments, the level converting unit may include an output unit, and a pull-down unit. The output unit may include first and second p-type metal oxide semiconductor (PMOS) transistors and may output the intermediate clock signal at a drain of the second PMOS transistor. The gate of the first PMOS transistor may be coupled to the drain of the second PMOS transistor, the gate of the second PMOS transistor may be coupled to the drain of the first PMOS transistor, and sources of the first and second PMOS transistors may be coupled to the second power-supply voltage. The pull-down unit may be coupled to the drain of the first PMOS transistor at a first node and coupled to the drain of the second PMOS transistor at a second node. The pull-down unit may pull down the first node based on the inverted clock signal, and pull down the second node based on the pulse signal and the enable signal. The pull-down unit may include a first n-type metal oxide semiconductor (NMOS) transistor that has a gate receiving the inverted clock signal, a drain coupled to the drain of the first PMOS transistor, and a source coupled to a ground voltage and a second NMOS transistor that has a gate receiving the enable signal, a drain coupled to the drain of the second PMOS transistor, and a third NMOS transistor that has a gate receiving the pulse signal, a drain coupled to the source of the second NMOS transistor, and a source coupled to the ground voltage.

In exemplary embodiments, the pull-down unit may include a first NMOS transistor that has a gate receiving the inverted clock signal, a drain coupled to the drain of the first PMOS transistor, and a source coupled to a ground voltage, a first transistor string having a plurality of cascade-connected NMOS transistors and a first terminal coupled to the drain of the second PMOS transistor, each gate of the NMOS transistors receiving the enable signal and a second NMOS transistor that has a gate receiving the pulse signal, a drain coupled to a second terminal of the first transistor string, and a source coupled to the ground voltage.

In exemplary embodiments, the latch circuit may include a retention latch that maintains a stable state of the intermediate clock signal and a third inverter that inverts the intermediate clock signal of which the stable state is maintained to provide the gated clock signal. The retention latch may include fourth and fifth inverters cross-coupled to each other. The retention latch may include a fourth inverter and a tri-state buffer cross-coupled to each other.

In exemplary embodiments of the present invention, a level-converted and clock-gated latch includes a pulse generator, an intermediate clock signal generator, and a latch circuit. The pulse generator is provided with first and second power-supply voltages, and generates a pulse signal in response to a clock signal. The clock signal has a first voltage level and the pulse signal has a second voltage level. The intermediate clock signal generator is provided with the second power-supply voltage, and generates an intermediate clock signal having the second voltage level, in response to an inverted clock signal, the clock signal, and an enable signal. The latch circuit is provided with the second power-supply voltage, latches the intermediate clock signal, and provides a gated clock signal having the second voltage level. The activation interval of the gated clock signal is controlled based on the enable signal.

In exemplary embodiments, the level of the first power-supply voltage may be lower than the level of the second power-supply voltage.

In exemplary embodiments, the pulse generator may include a first inverter, a delay unit, and a pulse-signal providing unit. The first inverter inverts the clock signal to provide the inverted clock signal. The delay unit delays the inverted clock signal to provide an inverted and delayed clock signal. The pulse signal providing unit is provided with the second power-supply voltage and provides the pulse signal, based on the clock signal and the inverted and delayed clock signal. In this exemplary embodiment, the pulse signal may be activated while the clock signal and the inverted and delayed clock signal are simultaneously activated. The pulse-signal providing unit may include a NAND gate that receives the inverted and delayed clock signal and the clock signal and a second inverter that inverts an output of the NAND gate to provide the pulse signal.

In exemplary embodiments, the intermediate clock signal generator may include an output unit, a pull-down unit and a pull-up unit. The output unit may include first and second p-type metal oxide semiconductor (PMOS) transistors and may output the intermediate clock signal at a drain of the second PMOS transistor. The gate of the first PMOS transistor may be coupled to the drain of the second PMOS transistor, a gate of the second PMOS transistor may be coupled to a drain of the first PMOS transistor, and sources of the first and second PMOS transistors may be coupled to the second power-supply voltage. The pull-down unit may be coupled to the drain of the first PMOS transistor at a first node and coupled to the drain of the second PMOS transistor at a second node. The pull-down unit may pull down the first node based on the inverted clock signal, and pull down the second node based on the pulse signal and the enable signal. The pull-down unit may include a first n-type metal oxide semiconductor (NMOS) transistor that has a gate receiving the inverted clock signal, a drain coupled to the drain of the first PMOS transistor, and a source coupled to a ground voltage, and a second NMOS transistor that has a gate receiving the enable signal, a drain coupled to the drain of the second PMOS transistor and a third NMOS transistor that has a gate receiving the pulse signal, a drain coupled to the source of the second NMOS transistor, and a source coupled to the ground voltage. The pull-up unit may be coupled between the second power-supply voltage and the second node. The pull-up unit may pull up the second node in response to the inverted clock signal. The pull-up unit may include a fourth NMOS transistor having a gate receiving the inverted clock signal, a drain coupled to the second power supply voltage, and a source coupled to the second node.

In exemplary embodiments of the present invention, a sequential logic circuit includes a level-converted and clock-gated latch and at least one flip-flop. The level-converted and clock-gated latch is provided with first and second power-supply voltages and provides a gated clock signal having a second voltage level, in response to a clock signal having a first voltage level. In this exemplary embodiment, the first and second power-supply voltages have different voltage levels with respect to each other, and an activation interval of the gated clock signal is controlled based on the enable signal. The at least one flip-flop is provided with the second power-supply voltage, receives an input signal and provides an output signal and an inverted output signal, synchronously with the gated clock signal.

Therefore, the level-converted and clock-gated latch according to exemplary embodiments of the present invention converts a clock signal swinging between a low power-supply voltage and the ground voltage to a gated clock signal swings between a high power-supply voltage and the ground voltage.

### BRIEF DESCRIPTION OF THE DRAWINGS

Exemplary embodiments of the present invention will be understood in more detail from the following descriptions taken in conjunction with the attached drawings.

FIG. 1 is circuit diagram illustrating a conventional clock-gated logic circuit.

FIG. 2 is a circuit diagram illustrating that a gated clock signal having a low swing level is applied to an inverter that is provided with a high voltage.

FIG. 3 illustrates that a gated clock signal via a level converter is applied to a flip-flop.

FIG. 4 is a circuit diagram illustrating a level-converted and clock-gated latch is according to an exemplary embodiment of the present invention.

FIG. 5 is a circuit diagram illustrating a delay unit in the level-converted and clock-gated latch of FIG. 4 according to an exemplary embodiment of the present invention.

FIGS. 6A through 6C are circuit diagrams illustrating the pull-down unit according to exemplary embodiments of the present invention.

FIG. 7 is a circuit diagram illustrating the retention latch according to an exemplary embodiment of the present invention.

FIG. 8 is a timing diagram illustrating signals of the level-converted and clock-gated latch of FIG. 4.

FIG. 9 is a circuit diagram illustrating a level-converted and clock-gated latch according to an exemplary embodiment of the present invention.

FIG. 10 is a timing diagram illustrating signals of the level-converted and clock-gated latch of FIG. 9.

FIG. 11 is a block diagram illustrating a sequential logic circuit according to an exemplary embodiment of the present invention.

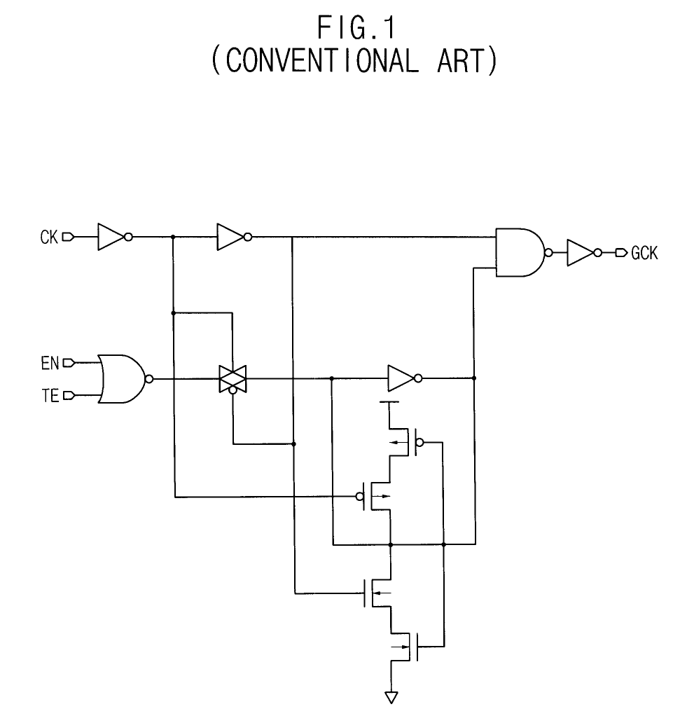

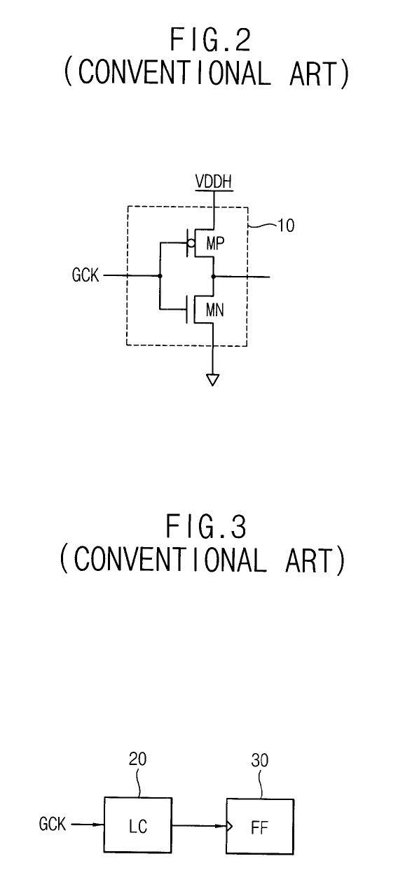

### DESCRIPTION OF EXEMPLARY EMBODIMENTS

Exemplary embodiments of the present invention now will be described more fully with reference to the accompanying drawings, in which exemplary embodiments of the invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the invention to those of ordinary skill in the art. Like reference numerals refer to like elements throughout this application.

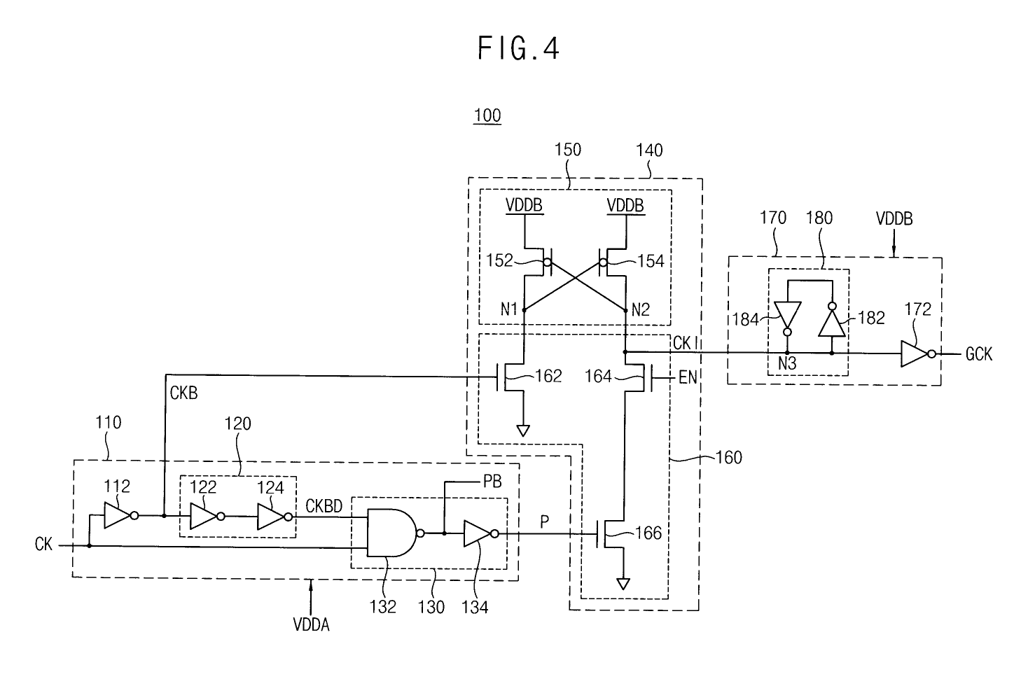

FIG. 4 is a circuit diagram illustrating a level-converted and clock-gated latch according to an exemplary embodiment of the present invention.

Referring to FIG. 4, a level-converted and clock-gated latch 100 includes a pulse generator 110, a level converting unit 140, and a latch circuit 170.

The pulse generator 110 includes a first inverter 112, a delay unit 120, and a pulse signal providing unit 130. The delay unit 120 includes two inverters 122 and 124 that are cascaded. The delay unit 120 may include an even number of inverters that are coupled in cascade. The pulse signal providing unit 130 includes a NAND gate 132 and a second inverter 134.

The first inverter 122 receives a clock signal CK and provides an inverted clock signal CKB. The delay unit 120 receives the inverted clock signal CKB and provides an inverted and delayed clock signal CKBD. The pulse signal providing unit 130 receives the clock signal CK and the inverted and delayed clock signal CKBD and provides a pulse signal P and an inverted pulse signal PB. The second inverter 134 inverts the inverted pulse signal PB to provide the pulse signal P. The pulse signal is activated while the inverted and delayed clock signal CKBD and the clock signal CK are simultaneously activated. Accordingly, an activation interval of the pulse signal P may be controlled based on the number of inverters included in the delay unit 120.

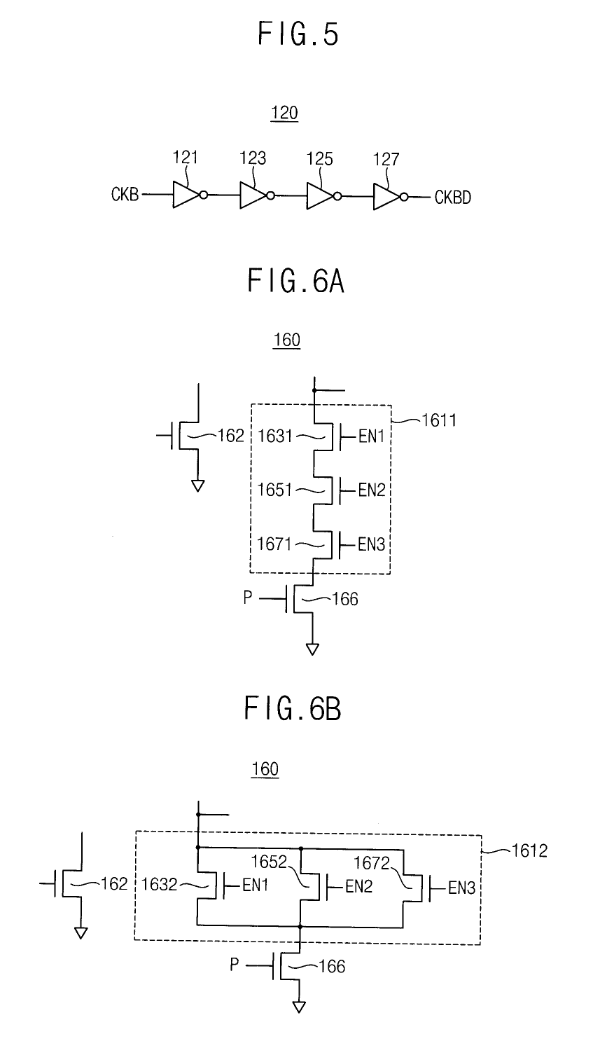

FIG. 5 is a circuit diagram illustrating a delay unit 120 in the level-converted and clock-gated latch of FIG. 4 according to an exemplary embodiment of the present invention.

Referring to FIG. 5, a delay unit 120 may include four inverters 121, 123, 125, and 127. The activation interval of the pulse signal P may increase according to the number of inverters included in the delay unit 120.

Referring again to FIG. 4, a first power-supply voltage VDDA is applied to the pulse generator 110. Therefore, the clock signal CK and the pulse signal P may swing between the first power-supply voltage VDDA and the ground voltage. When the first power-supply voltage VDDA corresponds to about 1 [V], the clock signal CK and the pulse signal P may swing between 1 [V] and 0 [V].

That is, the pulse generator 110 is provided with the first power-supply voltage VDDA and generates the pulse signal P having a level of the first power-supply voltage VDDA, in response to the clock signal CK.

The level converting unit 140 includes an output unit 150 and a pull-down unit 160. The output unit 140 includes first and second p-type metal oxide semiconductor (PMOS) transistors 152 and 154, respectively. The gate of the first PMOS transistor 152 is coupled to the drain of the second PMOS transistor 154, the gate of the second PMOS transistor 154 is coupled to a drain of the first PMOS transistor 152, and sources of the first and second PMOS transistors 152 and 154 are coupled to the second power-supply voltage VDDB. The pull-down unit 160 includes first, second, and third n-type metal oxide semiconductor (NMOS) transistors 162, 164, and 166. The first NMOS transistor 162 has a gate receiving the inverted clock signal CKB, a drain coupled to the drain of the first PMOS transistor 152 at a first node N1, and a source coupled to a ground voltage. The second NMOS transistor 164 has a gate receiving the enable signal EN, and a drain coupled to the drain of the second PMOS transistor 154 at a second node N2. The third NMOS transistor 166 has a gate receiving the pulse signal P, a drain coupled to the source of the second NMOS transistor 164, and a source coupled to the ground voltage. An intermediate clock signal CKI is provided at the second node N2, and the intermediate clock CKI signal has a level of the second power-supply voltage VDDB. That is, the level converting unit 140 provides the intermediate clock signal CKI having a level of the second power-supply voltage VDDB, in response to the inverted clock signal CKB, the pulse signal P, and the enable signal EN. That is, the level converting unit 140 converts the level of the first power-supply voltage VDDA of the clock signal CK and provides the intermediate clock signal CKI having the level of the second power-supply voltage VDDB. When the second power-supply voltage VDDB corresponds to about 2 [V], the intermediate clock signal CKI may swing between 2 [V] and 0 [V].

The latch circuit 170 includes a retention latch 180 and a third inverter 172. The retention latch 180 includes fourth and fifth inverters 182 and 184 that are mutually coupled. The fourth inverter 182 has an input terminal coupled to a third node N3. The fifth inverter 184 has an input terminal coupled to an output terminal of the fourth inverter 182, and an output terminal coupled to the third node N3. The retention latch 180 stably maintains a state of the intermediate clock signal CKI. The third inverter 172 has an input terminal coupled to the third node N3. The third inverter 172 inverts the intermediate clock signal CKI of which the state is stably maintained to provide a gated clock signal GCK.

The latch circuit 170 is also provided with the second power-supply voltage VDDB that is provided to the level converting unit 140. Thus, the gated clock signal GCK swings between the second power-supply voltage VDDB and the ground voltage. The retention latch 180 may be implemented with other devices instead of the inverters 182 and 184.

FIG. 7 is a circuit diagram illustrating the retention latch 180 according to an exemplary embodiment of the present invention.

Referring to FIG. 7, the retention latch 180 may include an inverter 183, and a tri-state buffer 185. The inverter 183 has an input terminal coupled to the third node N3. The tri-state buffer 182 has an input terminal coupled to an output terminal of the inverter 182, and an output terminal coupled to the third node N3. The tri-state buffer 182 has two control terminals that receive the pulse signal P and the inverted pulse signal PB that are provided from the pulse generator 110.

Referring again to FIG. 4, the gated clock signal GCK has the same activation interval as the clock signal CK, and whether the gated clock signal GCK is activated is determined by the enable signal EN. The level-converted and clock-gated latch 100 converts a level of the clock signal CK having a first voltage level, for example, the first power-supply voltage VDDA to a second voltage level, for example, the second power-supply voltage VDDB, to provide the gated clock signal GCK having the second voltage level. The second voltage level is greater than the first voltage level. The gated clock signal GCK may be provided to the flip-flops that operate at a higher voltage for providing high performance. A plurality of enable signals may be applied to the level converting unit 140 in complicated digital systems.

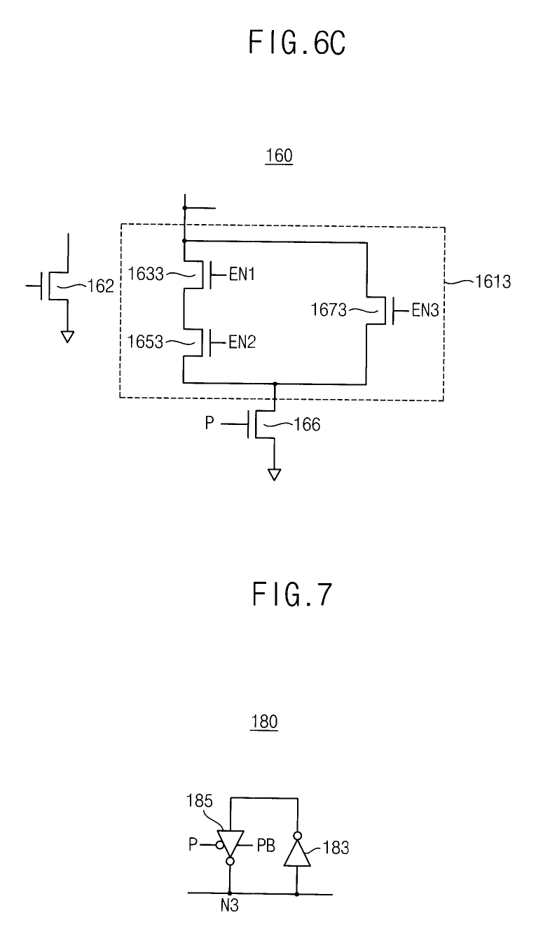

FIGS. 6A through 6C are circuit diagrams illustrating the pull-down unit 160 that receives a plurality of enable signals according to exemplary embodiments of the present invention.

Referring to FIG. 6A, a first transistor string 1611 may replace the second NMOS transistor 164 of FIG. 4. The first transistor string 1611 includes three NMOS transistors 1631, 1651, and 1671 that are cascode connected. Each of enable signals EN1, EN2, and EN3 is applied to each gate of the NMOS transistors 1631, 1651, and 1671, respectively. The circuit configuration of FIG. 6A may perform an AND logic function.

Referring to FIG. 6B, a second transistor string 1612 may replace the second NMOS transistor 164 of FIG. 4. The second transistor string 1612 includes three NMOS transistors 1632, 1652, and 1672 that are coupled in parallel. Each of the enable signals EN1, EN2, and EN3 is applied to each gate of the NMOS transistors 1632, 1652, and 1672, respectively. The circuit configuration of FIG. 6B may perform an OR logic function.

Referring to FIG. 6C, a third transistor string 1613 may replace the second NMOS transistor 164 of FIG. 4. The third transistor string 1613 includes three NMOS transistors 1633, 1653, and 1673. The NMOS transistors 1633 and 1653 are cascode coupled. The NMOS transistor 1673 is coupled to the NMOS transistors 1633 and 1653 in parallel. Each of the enable signals EN1, EN2, and EN3 is applied to each gate of the NMOS transistors 1633,1653, and 1673, respectively.

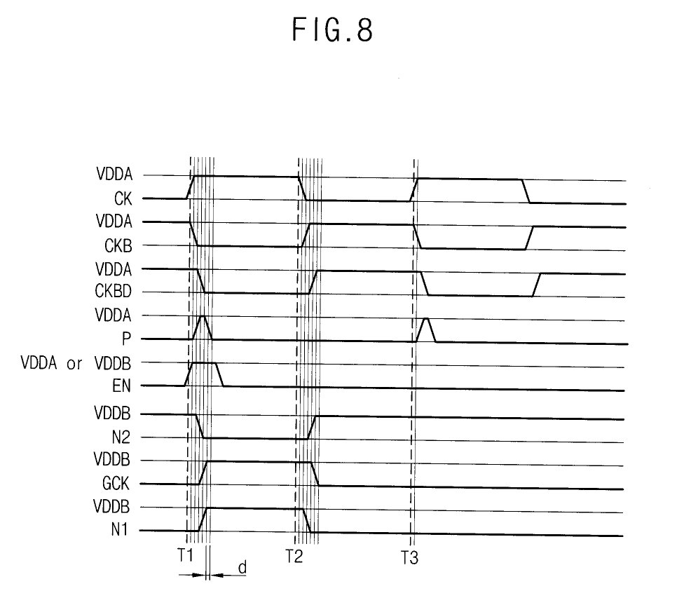

FIG. 8 is a timing diagram illustrating signals of the level-converted and clock-gated latch 100 of FIG. 4.

Referring to FIGS. 4 and 8, operation of the level-converted and clock-gated latch 100 of FIG. 4 will be described. An interval d denotes the time delay of the respective inverters included in the level-converted and clock-gated latch 100.

In FIG. 8, it is assumed that the clock signal is enabled at time T1, is disabled at time T2, and is enabled again at time T3.

The inverted clock signal CKB is disabled after a lapse of the time delay d from the time when the clock signal CK is enabled. The inverted and delayed clock signal CKBD is delayed by a time interval corresponding to two time delays 2d because of the inverters 122 and 124 included in the delay unit 120, as shown in FIG. 4. The pulse signal P is enabled after being delayed by the time delay d with respect to the time point when the clock signal CK and the inverted and delayed clock signal CKBD are simultaneously enabled. The enable signal EN is enabled at the same time as the clock signal CK is enabled, is maintained in the enabled state during about six time delays 6d, and is then disabled.

It is assumed that the first node N1 is a low level before time T1. Thus, before time T1, the second PMOS transistor 154 is turned on, and the second node N2 is a high level of the second power-supply voltage VDDB.

When the inverted clock signal CKB transitions to a low level, the first NMOS transistor 162 is turned off. At this time, the second NMOS transistor 164 is turned on by the enable signal EN, the third NMOS transistor 166 is turned on by the pulse signal P, and the second node N2 transitions from a high level to a low level. When the second node N2 transitions from the high level to the low level, the first PMOS transistor P1 is turned on, and the first node N1 transitions from the low level to the high level.

When the second node N2 transitions from the high level to the low level, the gated clock signal GCK transitions from the low level to the high level after being delayed by the time delay d. The logic states of the clock signal CK, the inverted clock signal CKB, the inverted and delayed clock signal CKBD, the pulse signal P, the enable signal EN, the first node N1, and the second node N2 are maintained in their respective states until time T2.

The intermediate clock signal CKI provided at the second node N2 swings between the second power-supply voltage VDDB and the ground voltage. Accordingly, the gated clock signal GCK also swings between the second power-supply voltage VDDB and the ground voltage.

The clock signal CK is disabled at time T2, and the inverted clock signal CKB is enabled after being delayed by the delay time d. The inverted and delayed clock signal CKBD is delayed by two delay times 2d with respect to the inverted clock signal CKB. When the inverted clock signal CKB transitions from the low level to the high level, the first node N1 transitions from the high level to the low level. When the first node N1 transitions from the high level to the low level, the second PMOS transistor 154 is turned on, and the second node N2 transitions from the low level to the high level. Accordingly, the gated clock signal GCK transitions from the high level to the low level. The logic states of the clock signal CK, the inverted clock signal CKB, the inverted and delayed clock signal CKBD, the pulse signal P, the enable signal EN, the first node N1 and the second node N2 are maintained in their respective states until time T3.

Because the logic state of the enable signal EN does not transition at time T3, the logic states of the first and second nodes N1 and N2 do not transition. Accordingly the logic states of the gated clock signal GCK does not transition. That is, the activation interval of the gated clock signal GCK may be controlled by the enable signal EN. In other words, at time T3, the clock signal CK switches, however, the gated clock signal GCK does not switch. Accordingly, unnecessary power consumption caused by switching may be reduced. In addition, the gated clock signal GCK swings between the second power-supply voltage VDDB and the ground voltage and, thus, the level converting function may be provided without requiring an extra level converter according to exemplary embodiments of the present invention.

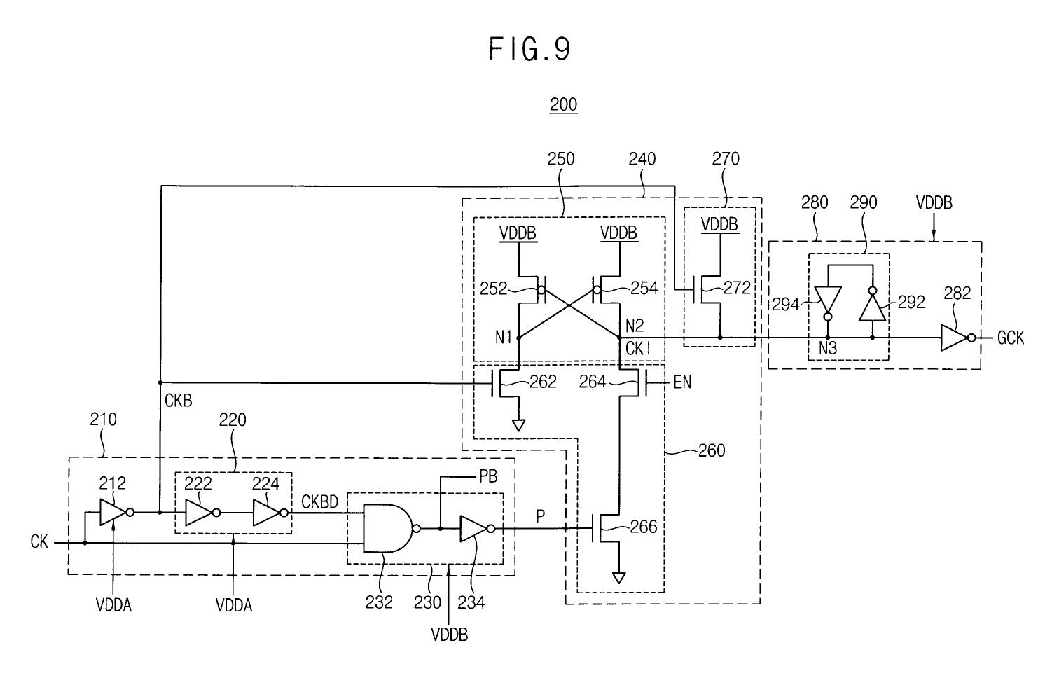

FIG. 9 is a circuit diagram illustrating a level-converted and clock-gated latch according to an exemplary embodiment of the present invention.

Referring to FIG. 9, a level-converted and clock-gated latch 200 includes a pulse generator 210, an intermediate clock generator 240, and a latch circuit 280.

The pulse generator 210 includes a first inverter 212, a delay unit 220, and a pulse signal providing unit 230. The delay unit 220 includes two inverters 222 and 224 that are cascade coupled. The delay unit 220 may include an even number of inverters that are coupled in cascade. The pulse signal providing unit 230 includes a NAND gate 232 and a second inverter 234. While the first power-supply voltage VDDA is provided to the pulse signal providing unit 130 of FIG. 4, the second power-supply voltage VDDB is provided to the pulse signal providing unit 230 of FIG. 9. The voltage level of the first power-supply voltage VDDA may be greater than the voltage level of the second power-supply voltage VDDB in the exemplary embodiment of FIG. 9.

The first inverter 222 receives a clock signal CK and provides an inverted clock signal CKB. The delay unit 220 receives the inverted clock signal CKB and provides an inverted and delayed clock signal CKBD. The pulse signal providing unit 230 receives the clock signal CK and the inverted and delayed clock signal CKBD and provides a pulse signal P and an inverted pulse signal PB. The second inverter 224 inverts the inverted pulse signal PB to provide the pulse signal P. The pulse signal P is activated while the inverted and delayed clock signal CKBD and the clock signal CK are simultaneously activated. Accordingly, an activation interval of the pulse signal P may be controlled based on the number of inverters included in the delay unit 220. The pulse generator 210 receives the clock signal CK swinging between the first power-supply voltage VDDA and the ground voltage to provide the pulse signal P swinging between the second power supply voltage VDDB and the ground voltage. While the level converting unit 140 performs level converting operation in FIG. 4, the pulse signal generating unit 230 performs level converting operation in FIG. 9.

The intermediate clock signal generator 240 includes an output unit 250, a pull-down unit 260 and a pull-up unit 270. The output unit 240 includes first and second PMOS transistors 252 and 254. The gate of the first PMOS transistor 252 is coupled to the drain of the second PMOS transistor 254, the gate of the second PMOS transistor 254 is coupled to a drain of the first PMOS transistor 252, and the sources of the first and second PMOS transistors 252 and 254 are coupled to the second power-supply voltage VDDB. The pull-down unit 260 includes first, second, and third NMOS transistors 262, 264, and 266, respectively. The first NMOS transistor 262 has a gate receiving the inverted clock signal CKB, a drain coupled to the drain of the first PMOS transistor 252 at a first node N1, and a source coupled to a ground voltage. The second NMOS transistor 264 has a gate receiving the enable signal EN, a drain coupled to the drain of the second PMOS transistor 254 at a second node N2. The third NMOS transistor 266 has a gate receiving the pulse signal P, a drain coupled to the source of the second NMOS transistor 264, and a source coupled to the ground voltage. An intermediate clock signal CKI is present at the second node N2, and the intermediate clock signal CKI has a level of the second power-supply voltage VDDB. The pull-up unit 270 includes a fourth NMOS transistor 272. The fourth NMOS transistor 272 has a drain coupled to the second power-supply voltage VDDB, a gate receiving the inverted clock signal CKB, and a source coupled to the second node N2. The pull-up unit 270 pulls up the second node N2 to a level of the second power-supply voltage VDDB when the inverted clock signal CKB is enabled.

The latch circuit 280 includes a retention latch 290 and a third inverter 282. The retention latch 290 includes fourth and fifth inverters 292 and 294 that are mutually coupled. The fourth inverter 292 has an input terminal coupled to a third node N3. The fifth inverter 294 has an input terminal coupled to an output terminal of the fourth inverter 2922, and an output terminal coupled to the third node N3. The retention latch 290 stably maintains a state of the intermediate clock signal CKI. The third inverter 282 has an input terminal coupled to the third node N3. The third inverter 282 inverts the intermediate clock signal of which the state is stably maintained to provide the gated clock signal GCK. The latch circuit 280 is also provided with the second power supply voltage VDDB.

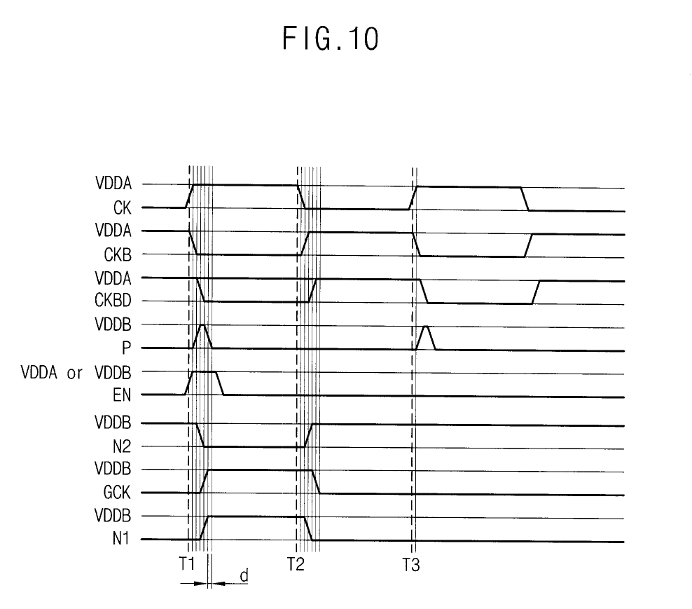

FIG. 10 is a timing diagram illustrating signals of the level-converted and clock-gated latch 200 of FIG. 9.

The logic states of the clock signal CK, the inverted clock signal CKB, the inverted and delayed clock signal CKBD, the pulse signal P, the enable signal EN, the first node N1 and the second node N2 of FIG. 10 are substantially similar to the logic states of the clock signal CK, the inverted clock signal CKB, the inverted and delayed clock signal CKBD, the pulse signal P, the enable signal EN, the first node N1 and the second node N2 as shown in FIG. 8 through times T1, T2 and T3 except that the pulse signal P swings between the second power-supply voltage VDDB and the ground voltage and the second node N2 quickly transitions to the high level at time T2 due to the pull-up operation of the fourth NMOS transistor 272 in FIG. 9. That is, the duty ratios of the gated clock signal GCK may be controlled by the fourth NMOS transistor 272 included in the pull-up unit 270.

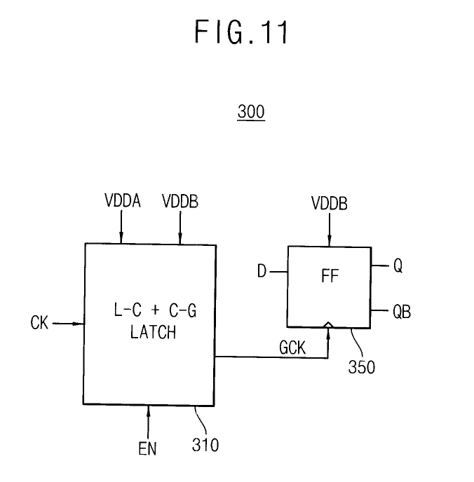

FIG. 11 is a block diagram illustrating a sequential logic circuit according to an exemplary embodiment of the present invention.

Referring to FIG. 11, a sequential logic circuit 300 includes a level-converted and clock-gated latch 310 and at least one flip-flop 350.

The level-converted and clock-gated latch 310 is provided with a first power-supply voltage VDDA and a second power-supply voltage VDDB that have different voltage levels. The level-converted and clock-gated latch 310 generates a gated-clock signal GCK in response to a clock signal CK. The clock signal CK swings between the first power-supply voltage VDDA and the ground voltage. The gated-clock signal GCK swings between the second power-supply voltage VDDB and the ground voltage. The voltage level of the first power-supply voltage VDDA may be greater than the voltage level of the second power-supply voltage VDDB in FIG. 11. The flip-flop 350 receives an input signal D to provide an output signal Q and an inverted output signal QB synchronously with the gated clock signal GCK. The level-converted and clock-gated latch 100 of FIG. 4 may be employed as the level-converted and clock-gated latch 310 of FIG. 11.

As described above, the level-converted and clock-gated latch and the sequential logic circuit including the level-converted and clock-gated latch according to exemplary embodiments of the present invention converts a clock signal swinging between a low power-supply voltage and the ground voltage to a gated clock signal swinging between a high power-supply voltage and the ground voltage. In addition, an activation interval of the gated clock signal is controlled by an enable signal. Therefore, the level converting function is provided without requiring an extra level converter and high performance is accomplished by providing the high power-supply voltage according to exemplary embodiments of the present invention.

While the exemplary embodiments of the present invention and their advantages have been described in detail, it should be understood that various changes, substitutions and alterations may be made herein without departing from the scope of the present invention.

What is claimed is:

1. A level-converted and clock-gated latch comprising:
a pulse generator that is provided with a first power-supply voltage, and that generates a pulse signal having a first voltage level in response to a clock signal fed thereto;
a level converting unit that is provided with a second power-supply voltage, and that generates an intermediate clock signal having a second voltage level in response to an inverted clock signal, the clock signal and an enable signal fed thereto; and
a latch circuit that is provided with the second power-supply voltage, that latches the intermediate clock signal, and provides a gated clock signal having the second voltage level, wherein an activation interval of the gated clock signal is controlled based on the enable signal.

2. The level-converted and clock-gated latch of claim 1, wherein a level of the first power-supply voltage is lower than a level of the second power-supply voltage.

3. The level-converted and clock-gated latch of claim 1, wherein the pulse generator comprises:
a first inverter that inverts the clock signal to provide the inverted clock signal;
a delay unit that delays the inverted clock signal to provide an inverted and delayed clock signal; and
a pulse signal providing unit that provides the pulse signal based on the clock signal and the inverted and delayed clock signal, wherein the pulse signal is activated while the clock signal and the inverted and delayed clock signal are simultaneously activated.

4. The level-converted and clock-gated latch of claim 3, wherein the delay unit comprises an even number of inverters that are coupled in cascade.

5. The level-converted and clock-gated latch of claim 4, wherein an activation interval of the pulse signal is controlled based on a number of inverters included in the delay unit.

6. The level-converted and clock-gated latch of claim 4, wherein the pulse signal providing unit comprises:
a NAND gate that receives the inverted and delayed clock signal and the clock signal; and
a second inverter that inverts an output of the NAND gate to provide the pulse signal.

7. The level-converted and clock-gated latch of claim 1, wherein the level converting unit comprises:
an output unit that includes first and second p-type metal oxide semiconductor (PMOS) transistors and that outputs the intermediate clock signal at a drain of the second PMOS transistor, a gate of the first PMOS transistor being coupled to the drain of the second PMOS transistor, a gate of the second PMOS transistor being coupled to a drain of the first PMOS transistor, and sources of the first and second PMOS transistors being coupled to the second power-supply voltage; and
a pull-down unit coupled to the drain of the first PMOS transistor at a first node and coupled to the drain of the second PMOS transistor at a second node, the pull-down unit pulling down a voltage at the first node based on the inverted clock signal and pulling down a voltage at the second node based on the pulse signal and the enable signal.

8. The level-converted and clock-gated latch of claim 7, wherein the pull-down unit comprises:
a first n-type metal oxide semiconductor (NMOS) transistor that has a gate receiving the inverted clock signal, a drain coupled to the drain of the first PMOS transistor, and a source coupled to a ground voltage; and
a second NMOS transistor that has a gate receiving the enable signal, a drain coupled to the drain of the second PMOS transistor; and
a third NMOS transistor that has a gate receiving the pulse signal, a drain coupled to the source of the second NMOS transistor, and a source coupled to the ground voltage.

9. The level-converted and clock-gated latch of claim 7, wherein the pull-down unit comprises:
a first NMOS transistor that has a gate receiving the inverted clock signal, a drain coupled to the drain of the first PMOS transistor, and a source coupled to a ground voltage;
a first transistor string having a plurality of cascade-connected NMOS transistors and a first terminal coupled to the drain of the second PMOS transistor, each gate of the NMOS transistors receiving the enable signal; and
a second NMOS transistor that has a gate receiving the pulse signal, a drain coupled to a second terminal of the first transistor string, and a source coupled to the ground voltage.

10. The level-converted and clock-gated latch of claim 1, wherein the latch circuit comprises:
a retention latch that maintains stably a state of the intermediate clock signal; and
a third inverter that inverts the intermediate clock signal of which the state is stably maintained to provide the gated clock signal.

11. The level-converted and clock-gated latch of claim 10, wherein the retention latch comprises fourth and fifth inverters coupled to each other.

12. The level-converted and clock-gated latch of claim 10, wherein the retention latch comprises a fourth inverter and a tri-state buffer coupled to each other.

13. A level-converted and clock-gated latch comprising:
a pulse generator that is provided with first and second power-supply voltages, and that generates a pulse signal in response to a clock signal fed thereto, the clock signal having a first voltage level and the pulse signal having a second voltage level;
an intermediate clock signal generator that is provided with the second power-supply voltage, and that generates an intermediate clock signal having the second voltage level, in response to an inverted clock signal, the clock signal, and an enable signal fed thereto; and
a latch circuit that is provided with the second power-supply voltage, that latches the intermediate clock signal, and that provides a gated clock signal having the second voltage level, wherein an activation interval of the gated clock signal is controlled based on the enable signal.

14. The level-converted and clock-gated latch of claim 13, wherein the pulse generator comprises:
a first inverter that inverts the clock signal to provide the inverted clock signal;
a delay unit that delays the inverted clock signal to provide an inverted and delayed clock signal; and
a pulse signal providing unit that is provided with the second power-supply voltage and that provides the pulse signal, based on the clock signal and the inverted and delayed clock signal, the pulse signal being activated while the clock signal and the inverted and delayed clock signal are simultaneously activated.

15. The level-converted and clock-gated latch of claim 14, wherein the pulse signal providing unit comprises:
a NAND gate that receives the inverted and delayed clock signal and the clock signal; and
a second inverter that inverts an output of the NAND gate to provide the pulse signal.

16. The level-converted and clock-gated latch of claim 13, wherein the intermediate clock signal generator comprises:
an output unit that includes first and second p-type metal oxide semiconductor (PMOS) transistors and outputs the intermediate clock signal at a drain of the second PMOS transistor, a gate of the first PMOS transistor being coupled to the drain of the second PMOS transistor, a gate of the second PMOS transistor being coupled to a drain of the first PMOS transistor, and sources of the first and second PMOS transistors being coupled to the second power-supply voltage;
a pull-down unit coupled to the drain of the first PMOS transistor at a first node and coupled to the drain of the second PMOS transistor at a second node, the pull-down unit pulling down a voltage at the first node based on the inverted clock signal and pulling down a voltage at the second node based on the pulse signal and the enable signal; and
a pull-up unit coupled between the second power-supply voltage and the second node, the pull-up unit pulling up the voltage at the second node in response to the inverted clock signal.

17. The level-converted and clock-gated latch of claim 16, wherein the pull-down unit comprises:
a first n-type metal oxide semiconductor (NMOS) transistor that has a gate receiving the inverted clock signal, a drain coupled to the drain of the first PMOS transistor, and a source coupled to a ground voltage;
a second NMOS transistor that has a gate receiving the enable signal, a drain coupled to the drain of the second PMOS transistor; and
a third NMOS transistor that has a gate receiving the pulse signal, a drain coupled to the source of the second NMOS transistor, and a source coupled to the ground voltage, and
wherein the pull-up unit comprises a fourth NMOS transistor having a gate receiving the inverted clock signal, a drain coupled to the second power-supply voltage and a source coupled to the second node.

18. The level-converted and clock-gated latch of claim 15, wherein the latch circuit comprises:
a retention latch that includes third and fourth inverters that maintains stably a state of the intermediate clock signal, the third and fourth inverters being cross-coupled to the second node with respect to each other; and
a third inverter that inverts the intermediate clock signal of which the state is stably maintained to provide the gated clock signal.

19. A sequential logic circuit comprising:
a level-converted and clock-gated latch that is provided with first and second power-supply voltages and that provides a gated clock signal having a second voltage level, in response to a clock signal having a first voltage level, the first and second power-supply voltages having different voltage levels with respect to each other, and an activation interval of the gated clock signal being controlled based on an enable signal; and
at least one flip-flop that is provided with the second power-supply voltage, receives an input signal and provides an output signal and an inverted output signal, synchronously with the gated clock signal.

20. The sequential logic circuit of claim 19, wherein the level-converted and clock-gated latch comprises:
a pulse generator that is provided with the first power-supply voltage, and generates a pulse signal having a first voltage level, in response to the clock signal;
a level converting circuit that is provided with the second power-supply voltage, and generates an intermediate clock signal having a second voltage level, in response to an inverted clock signal, the clock signal, and the enable signal; and
a latch circuit that is provided with the second power-supply voltage, latches the intermediate clock signal, and provides the gated clock signal having the second voltage level.
